(19) United States
(12) Patent Application Publication
(10) Pub. No.: US 2023/0151274 A1
(43) Pub. Date: May 18, 2023

(54) Method for selective etching Si in the presence of silicon nitride, its composition and application thereof

(71) Applicant: CJ Technology Co., Ltd., New Taipei City (TW)

(72) Inventors: Tzung Chi Hsieh, New Taipei City (TW); Mo Hsun Tsai, New Taipei City (TW)

(21) Appl. No.: 17/990,011

(22) Filed: Nov. 18, 2022

Related U.S. Application Data
(62) Division of application No. 17/526,075, filed on Nov. 15, 2021.

(51) Int. Cl. C09K 13/00; C11D 7/32; H01L 21/3213; H01L 21/28; H01L 21/306

(52) U.S. Cl. CPC C09K 13/00; C11D 7/3209; C11D 7/3218; H01L 21/32134; H01L 21/28035; H01L 21/30604

(57) ABSTRACT

A method for selective etching Si in the presence of silicon nitride and an etching composition with high Si/Si3N4 etching selectivity are disclosed. Particularly, the method for selective etching Si in the presence of silicon nitride is to apply the etching composition with high Si/Si3N4 etching selectivity in the etching process, and the etching composition with high Si/Si3N4 etching selectivity comprises about 0.5 wt. % to about 10 wt. % of at least one quaternary ammonium compound, about 5 wt. % to about 55 wt. % of at least one primary amine, about 15 wt. % to about 80 wt. % of at least one polyol, and about 10 wt. % to about 35 wt. % water based on total weight of the etching composition.

### CROSS REFERENCE TO RELATED APPLICATIONS

This is a divisional of U.S. Ser. No. 17/526,075, filed Nov. 15, 2021 by the same inventors, and claims priority there from. This divisional application contains rewritten claims to the restricted-out subject matter of original claims.

### TECHNICAL FIELD

The invention discloses a method for selective etching Si in the presence of silicon nitride and its composition. In particular, the etching composition comprises at least one quaternary ammonium compound, at least one primary amine, at least one polyol, and water and has a Si/Si3N4 etching selectivity more than 5000/1.

### BACKGROUND

In a typical integrated circuit formation process, a passivation layer is formed to protect the internal semiconductor devices after the completion of metallization. The passivation layers of microchips inhibit the attacks from chemicals, moisture, and contaminants to ensure reliable operation of electronic products. Silicon nitride (Si₃N₄) is the common passivation material.

In an advanced semiconductor fabrication, an etching process for making nano-dimension silicon pattern is critical. Because the device become more miniaturized and fragile in advanced process, the passivation layers had to be protected from micro-etching, so a special silicon etchant is required for achieving the purpose. However, traditional silicon etchants usually comprise HF or TMAH, and cause Si₃N₄ layer corrosion in the etching process. Therefore, the damaged passivation layer produced undesirable effects such as current collapse and leakage current. As a result, a silicon etchant for competently protecting Si₃N₄ layer from corrosion in the etching process is required.

Based on the aforementioned, a novel silicon etchant for using in advanced semiconductor fabrication that would not damage Si₃N₄ is emergent to be developed.

### SUMMARY OF THE INVENTION

In one aspect, the invention discloses a method for selective etching Si in the presence of silicon nitride. The method comprises a step of applying a specific etching composition in an etching process. Furthermore, the method is able to avoid damage of silicon nitride.

Typically, the etching composition comprises about 0.5 wt. % to about 10 wt. % of at least one quaternary ammonium compound, about 5 wt. % to about 55 wt. % of at least one primary amine, about 15 wt. % to about 80 wt. % of at least one polyol, and about 10 wt. % to about 35 wt. % water based on total weight of the etching composition.

In particular, the method has a Si/Si3N4 etching selectivity more than 5000/1. Accordingly, the aforementioned method for selective etching Si in the presence of silicon nitride is very suitable for applying in a nanoscale Si pattern etching process for fabricating semiconductors.

In another aspect, the invention provides an etching composition with Si/Si3N4 etching selectivity more than 5000/1. The etching composition comprises about 0.5 wt. % to about 10 wt. % of at least one quaternary ammonium compound, about 5 wt. % to about 55 wt. % of at least one primary amine, about 15 wt. % to about 80 wt. % of at least one polyol, and about 10 wt. % to about 35 wt. % water based on total weight of the etching composition.

The aforementioned etching composition with Si/Si3N4 etching selectivity more than 5000/1 is able to protect Si₃N₄ layer from corrosion in the etching process and well using in advanced semiconductor fabrication.

In a third aspect, the invention discloses a nanoscale Si pattern etching process for fabricating semiconductors. The process comprises a step of applying an etching composition on a substrate to form a Si pattern having a gate width of 1-28 nm. Typically, the etching composition comprises about 0.5 wt. % to about 10 wt. % of at least one quaternary ammonium compound, about 5 wt. % to about 55 wt. % of at least one primary amine, about 15 wt. % to about 80 wt. % of at least one polyol, and about 10 wt. % to about 35 wt. % water based on total weight of the etching composition.

Typically, the substrate comprises a silicon nitride structure, for example, the substrate comprises a silicon nitride film or a silicon nitride layer on its surfaces.

Preferably, the etching composition has a Si/Si3N4 etching selectivity more than 5000/1.

Accordingly, the invention discloses a method for selective etching Si in the presence of silicon nitride, its etching composition and application in fabrication of semiconductors. One of the unexpectable technical effects is that the invented method has a Si/Si3N4 etching selectivity more than 5000/1, and is able to selectively etch silicon on a substrate comprises a silicon nitride structure. This feature successfully avoids corrosion and other damage of silicon nitride during fabricating process of semiconductors.

### EMBODIMENTS

In a first embodiment, the invention discloses a method for selective etching Si in the presence of silicon nitride, comprising applying an etching composition in an etching process, wherein the etching composition comprises about 0.5 wt. % to about 10 wt. % of at least one quaternary ammonium compound, about 5 wt. % to about 55 wt. % of at least one primary amine, about 15 wt. % to about 80 wt. % of at least one polyol, and about 10 wt. % to about 35 wt. % water based on total weight of the etching composition.

In one example of the first embodiment, the method is highly specific to attack Si and has a Si/Si3N4 etching selectivity more than 5000/1.

In one example of the first embodiment, the quaternary ammonium compound has a structure as shown in R₁R₂R₃R₄N⁺OH⁻, where R1, R2, R3 and R4 are C1-C4 linear chain alkyl groups, C1-C4 branched chain alkyl groups, C1-C4 linear alcohol or C1-C4 branched alcohol, respectively.

In one example of the first embodiment, the quaternary ammonium compound comprises tetramethylammonium hydroxide (TMAH), ethyltrimethylammonium hydroxide (ETMAH), tetraethylammonium hydroxide (TEAH), 2-hydroxyethyl trimethylammonium hydroxide or their mixture.

In one example of the first embodiment, the primary amine comprises 2-aminoethanol, 3-Aminopropan-1-ol, 4-Amino-1-butanol or their mixture.

In one example of the first embodiment, the polyol comprises ethane-1,2-diol, 1,2-propanediol, 1,3-propanediol or their mixture.

In one example of the first embodiment, the method is to apply in a nanoscale Si pattern etching process for fabricating semiconductors. Preferably, the nanoscale Si pattern has a gate width of 1-28 nm. More preferably, the nanoscale Si pattern has a gate width of 1-10 nm.

In a second embodiment, the invention provides an etching composition with Si/Si3N4 etching selectivity more than 5000/1. The etching composition with Si/Si3N4 etching selectivity more than 5000/1 comprises about 0.5 wt. % to about 10 wt. % of at least one quaternary ammonium compound, about 5 wt. % to about 55 wt. % of at least one primary amine, about 15 wt. % to about 80 wt. % of at least one polyol, and about 10 wt. % to about 35 wt. % water based on total weight of the etching composition.

In one example of the second embodiment, the quaternary ammonium compound has a structure as shown in R₁R₂R₃R₄N⁺OH⁻, where R1, R2, R3 and R4 are C1-C4 linear chain alkyl groups, C1-C4 branched chain alkyl groups, C1-C4 linear alcohol or C1-C4 branched alcohol, respectively.

In one example of the second embodiment, the quaternary ammonium compound comprises tetramethylammonium hydroxide (TMAH), ethyltrimethylammonium hydroxide (ETMAH), tetraethylammonium hydroxide (TEAH), 2-hydroxyethyl trimethylammonium hydroxide or their mixture.

In one example of the second embodiment, the primary amine comprises 2-aminoethanol, 3-Aminopropan-1-ol, 4-Amino-1-butanol or their mixture.

In one example of the second embodiment, the polyol comprises ethane-1,2-diol, 1,2-propanediol, 1,3-propanediol or their mixture.

In one example of the second embodiment, the etching composition with Si/Si3N4 etching selectivity more than 5000/1 is to apply in a nanoscale Si pattern etching process for fabricating semiconductors. Preferably, the nanoscale Si pattern has a gate width of 1-28 nm. More preferably, the nanoscale Si pattern has a gate width of 1-10 nm.

In a third embodiment, the invention discloses a nanoscale Si pattern etching process for fabricating semiconductors. The process comprises a step of applying an etching composition on a substrate to form a Si pattern having a gate width of 1-28 nm, wherein the etching composition comprises about 0.5 wt. % to about 10 wt. % of at least one quaternary ammonium compound, about 5 wt. % to about 55 wt. % of at least one primary amine, about 15 wt. % to about 80 wt. % of at least one polyol, and about 10 wt. % to about 35 wt. % water based on total weight of the etching composition.

Preferably, the nanoscale Si pattern has a gate width of 1-28 nm. More preferably, the nanoscale Si pattern has a gate width of 1-10 nm.

In one example of the third embodiment, the substrate comprises a silicon nitride structure, for example, the substrate comprises a silicon nitride film or a silicon nitride layer on its surfaces.

In one example of the third embodiment, the etching composition has a Si/Si3N4 etching selectivity more than 5000/1.

In one example of the third embodiment, the quaternary ammonium compound has a structure as shown in R₁R₂R₃R₄N⁺OH⁻, where R1, R2, R3 and R4 are C1-C4 linear chain alkyl groups, C1-C4 branched chain alkyl groups, C1-C4 linear alcohol or C1-C4 branched alcohol, respectively.

In one example of the third embodiment, the quaternary ammonium compound comprises tetramethylammonium hydroxide (TMAH), ethyltrimethylammonium hydroxide (ETMAH), tetraethylammonium hydroxide (TEAH), 2-hydroxyethyl trimethylammonium hydroxide or their mixture.

In one example of the third embodiment, the primary amine comprises 2-aminoethanol, 3-Aminopropan-1-ol, 4-Amino-1-butanol or their mixture.

In one example of the third embodiment, the polyol comprises ethane-1,2-diol, 1,2-propanediol, 1,3-propanediol or their mixture.

Following working examples are provided to prove the technical effects of the invention.

Measurement of Etching Rate of the Etching Composition and Si/Si₃N₄ Etching Selectivity

The measurement of etching rate of the etching composition is performed at 60° C. Testing specimen is a wafer surface coating an amorphous silicon film and a wafer surface coating a Si₃N₄ film, respectively. The amorphous silicon film has a thickness of 2000 Å (Angstrom), and the Si₃N₄ film has a thickness of 600 Å (Angstrom). Measure the thickness of the amorphous silicon film and Si₃N₄ film before etching process by Ellipsometer and obtain initial thickness value X Å, respectively. Then, completely immerse the testing specimen into the silicone etchant at 60° C. After T (1˜60) minutes, remove the testing specimen from the silicone etchant and wash the testing specimen with pure water until no residual silicone etchant on the surface. Measure the thickness of the amorphous silicon film and Si₃N₄ film again and obtain a thickness value Y Å. The etching rate of the silicone etchant is calculated by the following equation.

The etching rate(Å/min)=(XÅ−YÅ)/T(Time(min))

According to the aforementioned measurement and equation, the etching rate of amorphous silicon (Si) and Si₃N₄ are obtained. Si/Si₃N₄ etching selectivity of the silicon etchant is calculated by the etching rate of amorphous silicon (Si) divided by the etching rate of Si₃N₄.

Eleven etching compositions are evaluated their performance. The etching compositions, the etching rate of amorphous silicon (Si), the etching rate of Si₃N₄ and Si/Si₃N₄ etching selectivity are list in TABLE 1. The etching compositions used in examples 1-6 are formulated according to the present invention. The etching compositions used in examples 7-11 are formulated according to traditional technology.

TABLE 1

| | Quaternary | | | Etching rate | Etching rate | Si/Si₃N₄ |
|---|---|---|---|---|---|---|
| | ammonium | | | of Si | of Si₃N₄ | etching |
| Example | hydroxide | Amine | Polyol | (Å/min) | (Å/min) | selectivity |
| 1 | TMAH¹ 1.5% | MEA⁴ 10% | EG⁵ 70% | 305 | 0.02 | 15250 |
| 2 | TMAH 1.5% | MEA 40% | EG 30% | 326 | 0.04 | 8150 |
| 3 | ETMAH² 2.0% | MEA 10% | EG 70% | 359 | 0.03 | 11967 |
| 4 | ETMAH 3.0% | MEA 40% | EG 30% | 422 | 0.06 | 7033 |
| 5 | Choline OH³ 5% | MEA 10% | EG 70% | 435 | 0.07 | 6214 |
| 6 | Choline OH 8% | MEA 40% | EG 30% | 558 | 0.1 | 5580 |
| 7 | TMAH 1.5% | | | 1022 | 1.9 | 538 |
| 8 | TMAH 1.5% | MEA 50% | | 381 | 0.19 | 2005 |
| 9 | TMAH 1.5% | | EG 50% | 376 | 0.17 | 2212 |
| 10 | ETMAH 1.8% | | | 1164 | 2.1 | 554 |
| 11 | Choline OH 5% | MEA 20% | EG 30% | 527 | 0.24 | 2196 |

1. TMAH: Tetramethylammonium hydroxide
2. ETMAH: Ethyltrimethylammonium hydroxide
3. Choline OH: 2-Hydroxyethyltrimethylammonium hydroxide
4. MEA: Monoehtanolamine
5. EG: Ethylene glycol

According to TABLE 1, obviously, the etching compositions prepared according to the present invention have Si/Si₃N₄ etching selectivity more than 5000/1, and are suitable for applying in a nanoscale Si pattern etching process for fabricating semiconductors. Preferably, the invented method for selective etching Si in the presence silicon nitride is used in fabrication of nanoscale Si patterns having a gate width of 1-28 nm. Therefore, the present invention has an unexpectable effect when compared to the traditional or known etching compositions.

Obviously, many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. A method for selective etching Si in the presence of silicon nitride, comprising: applying an etching composition in an etching process, wherein the etching composition comprises about 0.5 wt. % to about 10 wt. % of at least one quaternary ammonium compound, about 5 wt. % to about 55 wt. % of at least one primary amine, about 15 wt. % to about 80 wt. % of at least one polyol, and about 10 wt. % to about 35 wt. % water based on total weight of the etching composition.

2. The method of claim 1, wherein the etching composition has a Si/Si3N4 etching selectivity more than 5000/1.

3. The method of claim 1, wherein the quaternary ammonium compound has a structure of R₁R₂R₃R₄N⁺OH⁻, where R1, R2, R3 and R4 are C1-C4 linear chain alkyl groups, C1-C4 branched chain alkyl groups, C1-C4 linear alcohol or C1-C4 branched alcohol, respectively.

4. The method of claim 1, wherein the quaternary ammonium compound comprises tetramethylammonium hydroxide (TMAH), ethyltrimethylammonium hydroxide (ETMAH), tetraethylammonium hydroxide (TEAH), 2-hydroxyethyl trimethylammonium hydroxide or their mixture.

5. The method of claim 1, wherein the primary amine comprises 2-aminoethanol, 3-Aminopropan-1-ol, 4-Amino-1-butanol or their mixture.

6. The method of claim 1, wherein the polyol comprises ethane-1,2-diol, 1,2-propanediol, 1,3-propanediol or their mixture.

7. The method of claim 1, being applying in a nanoscale Si pattern etching process for fabricating semiconductors.

8. A nanoscale Si pattern etching process for fabricating semiconductors, comprising: applying an etching composition on a substrate to form a Si pattern having a gate width of 1-28 nm, wherein the etching composition comprises about 0.5 wt. % to about 10 wt. % of at least one quaternary ammonium compound, about 5 wt. % to about 55 wt. % of at least one primary amine, about 15 wt. % to about 80 wt. % of at least one polyol, and about 10 wt. % to about 35 wt. % water based on total weight of the etching composition.

9. The nanoscale Si pattern etching process of claim 8, wherein the substrate comprises a silicon nitride structure.

10. The nanoscale Si pattern etching process of claim 8, wherein the etching composition has a Si/Si3N4 etching selectivity more than 5000/1.

11. The nanoscale Si pattern etching process of claim 8, wherein the quaternary ammonium compound has a structure as shown in R₁R₂R₃R₄N⁺OH⁻, where R1, R2, R3 and R4 are C1-C4 linear chain alkyl groups, C1-C4 branched chain alkyl groups, C1-C4 linear alcohol or C1-C4 branched alcohol, respectively.

12. The nanoscale Si pattern etching process of claim 8, wherein the quaternary ammonium compound comprises tetramethylammonium hydroxide (TMAH), ethyltrimethylammonium hydroxide (ETMAH), tetraethylammonium hydroxide (TEAH), 2-hydroxyethyl trimethylammonium hydroxide or their mixture.

13. The nanoscale Si pattern etching process of claim 8, wherein the primary amine comprises 2-aminoethanol, 3-Aminopropan-1-ol, 4-Amino-1-butanol or their mixture.

14. The nanoscale Si pattern etching process of claim 8, wherein the polyol comprises ethane-1,2-diol, 1,2-propanediol, 1,3-propanediol or their mixture.
